(19) United States
(12) Patent Application Publication
(10) Pub. No.: US 2021/0234134 A1
(43) Pub. Date: Jul. 29, 2021

(54) ANTI-PEEPING DISPLAY PANEL AND ANTI-PEEPING DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Puyu QI, Beijing (CN); Bing ZHANG, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 17/042,528

(22) PCT Filed: Mar. 26, 2020
(86) PCT No.: PCT/CN2020/081373

§ 371 Date: Sep. 28, 2020

(30) Foreign Application Priority Data
Jun. 6, 2019 (CN) 201910489957.X

(51) Int. Cl. H01L 51/52; H01L 27/32

(52) U.S. Cl. CPC H01L 51/5284; H01L 51/5253; H01L 27/322

(57) ABSTRACT

An anti-peeping display panel and an anti-peeping display apparatus are disclosed. The anti-peeping display panel includes: a plurality of pixel units, each of the pixel units including a plurality of sub-pixels; a color filter layer including a plurality of color filter units in one-to-one correspondence with the plurality of sub-pixels, each of the color filter units being configured to filter light emitted by a corresponding sub-pixel; and a black matrix layer including a plurality of black matrices, each of the black matrices being located in an area adjoining adjacent color filter units, the black matrix being configured to block at least part of light emitted by a sub-pixel adjacent to the black matrix, and an included angle between an emission direction of the at least portion of light and a normal of a light emergent surface of the sub-pixel being greater than or equal to 40°.

### CROSS-REFERENCE TO RELATED APPLICATIONS

The present application claims priority to Chinese Patent Application No. 201910489957.X, filed on Jun. 6, 2019 and entitled “Anti-peeping Apparatus and Display Apparatus”, for any purpose, the disclosure of which is incorporated herein by reference in its entirety as part of the present application.

### TECHNICAL FIELD

Embodiments of the present disclosure relate to an anti-peeping display panel and an anti-peeping display apparatus.

### BACKGROUND

At present, products for adjusting a viewing angle are mainly Light Control Films (LCFs); however, due to a protective layer and adhesive existing therein, such an LCF film usually has a thickness of approximately 400 μm. A louver structure in the LCF film that controls the viewing angle has a thickness of approximately 50 μm.

### SUMMARY

Embodiments of the present disclosure relate to an anti-peeping display panel and an anti-peeping display apparatus.

Accordingly to first aspect of the present disclosure, it is provided an anti-peeping display panel, comprising:

a plurality of pixel units, each of the plurality of the pixel units comprising a plurality of sub-pixels, each of the plurality of the sub-pixels comprising an electroluminescent layer;

a color filter layer, comprising a plurality of color filter units, the plurality of the color filter units being in one-to-one correspondence with the plurality of the sub-pixels, each of the plurality of the color filter units being configured to filter light emitted from a corresponding sub-pixel; and

a black matrix layer, comprising a plurality of black matrices, each of the plurality of the black matrices being located in an area adjoining adjacent color filter units, the black matrix being configured to block at least part of light emitted from the sub-pixel adjacent to the black matrix, and an included angle between an emission direction of the at least portion of light and a normal of a light emergent surface of the sub-pixel being greater than or equal to 40°.

In at least some embodiments, each of the sub-pixels does not overlap with the black matrix adjacent to the each of the sub-pixels in a direction perpendicular to the light emergent surface of each of the sub-pixels; and the light emergent surface of each of the sub-pixels comprises at least one side edge, and a maximum value of an included angle between light emitted through the at least one side edge and propagating outward through the color filter unit corresponding to the sub-pixel and the normal is 40°.

In at least some embodiments, the anti-peeping display panel further comprises a pixel defining layer, wherein the pixel defining layer defines a plurality of pixel regions, the plurality of the sub-pixels are respectively located within the plurality of the pixel regions, and an orthographic projection of each of the black matrices on the pixel defining layer is located within the pixel defining layer.

In at least some embodiments, the light emergent surface of each of the sub-pixels comprises at least one side edge, and a distance between the at least one side edge and an orthographic projection of the black matrix adjacent to the at least one side edge on the pixel defining layer is from 0 to 3 microns.

In at least some embodiments, the light emergent surface of each of the sub-pixels has a rectangle shape and comprises four side edges, a distance between each of the four side edges and the orthographic projection of the black matrix adjacent to the side edge on the pixel defining layer is zero; and a thickness of the black matrix layer is a, and a vertical distance from the light emergent surface of each of the sub-pixels to a surface of the black matrix that is close to the sub-pixel is b, wherein, a+b≥40 microns.

In at least some embodiments, the light emergent surface of each of the sub-pixels has a rectangle shape and comprises four side edges, a distance between each of the four side edges and the orthographic projection of the black matrix adjacent to the side edge on the pixel defining layer is greater than zero; and a thickness of the black matrix layer is a, and a vertical distance from the light emergent surface of each of the sub-pixels to a surface of the black matrix that is close to the sub-pixel is b, wherein, b>a, and a ratio of b to a is greater than or equal to 8.

In at least some embodiments, a is approximately in a range from 0 microns to 5 microns; and b is approximately in a range from 40 microns to 80 microns.

In at least some embodiments, the anti-peeping display panel further comprises an encapsulation layer, wherein the encapsulation layer is located between the color filter layer and each of the sub-pixels and is configured to encapsulate the plurality of the pixel units; and the encapsulation layer comprises an inorganic material layer and an organic material layer which are alternately arranged.

In at least some embodiments, the encapsulation layer comprises at least two organic material layers; the encapsulation layer comprises a first layer closest to the pixel unit and a last layer closest to the color filter layer; and the first layer and the last layer are both the inorganic material layers.

In at least some embodiments, a thickness of the inorganic material layer is approximately from 0.5 microns to 1 micron; and a thickness of the organic material layer is approximately from 8 microns to 20 microns.

In at least some embodiments, a vertical distance from the light emergent surface of each of the sub-pixels to a surface of the black matrix that is close to the sub-pixel is equal to the thickness of the encapsulation layer.

In at least some embodiments, the sub-pixels comprise a red sub-pixel, a green sub-pixel, and a blue sub-pixel; and a distance between the red sub-pixel and an orthographic projection of the black matrix adjacent to the red sub-pixel on the pixel defining layer is greater than or equal to a distance between the green sub-pixel and an orthographic projection of the black matrix adjacent to the green sub-pixel on the pixel defining layer.

In at least some embodiments, the distance between the green sub-pixel and the orthographic projection of the black matrix adjacent to the green sub-pixel on the pixel defining layer is greater than or equal to a distance between the blue sub-pixel and an orthographic projection of the black matrix adjacent to the blue sub-pixel on the pixel defining layer.

Accordingly to second aspect of the present disclosure, it is provided an anti-peeping display apparatus, comprising the afore-mentioned anti-peeping display panel.

In at least some embodiments, the anti-peeping display apparatus further comprises: a driving substrate, wherein the anti-peeping display panel is provided on the driving substrate; and the driving substrate comprises a driving circuit, the driving circuit is configured to drive each of the sub-pixels to emit light.

In at least some embodiments, the anti-peeping display apparatus further comprises: a protective layer, a touch sensing layer and a cover plate that are sequentially arranged on a side of the anti-peeping display panel that is away from the driving substrate.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a structural schematic diagram of an OLED display module adopting a circular polarizer according to the present disclosure;

FIG. 2 is a structural schematic diagram of an OLED display module adopting a COE structure according to an embodiment of the present disclosure;

FIG. 3 is a schematic diagram of principle of the COE structure for implementing an anti-peeping function according to an embodiment of the present disclosure;

FIG. 4 is a structural schematic diagram of an anti-peeping display panel according to an embodiment of the present disclosure;

FIG. 5 is a top view of an anti-peeping display panel according to another embodiment of the present disclosure;

FIG. 6 is a structural schematic diagram of an encapsulation layer according to an embodiment of the present disclosure;

FIG. 7 show an EL emission spectrum and a CF transmission spectrum of sub-pixels of different colors according to an embodiment of the present disclosure; and

FIG. 8 is a structural schematic diagram of an anti-peeping display apparatus according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

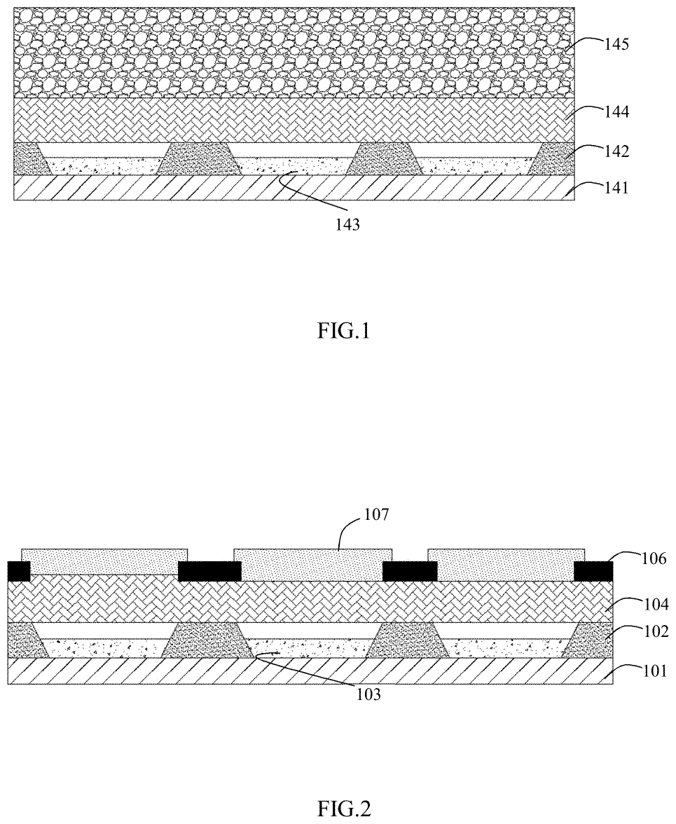

As a concept of flexible foldable displays becomes more and more popular, manufacturers of Organic Light-Emitting Diode (OLED) display panels are all keen on making the displays thinner. An ordinary OLED module structure is usually implemented by attaching a circular polarizer onto a Thin Film Encapsulation (TFE) layer. As illustrated in FIG. 1, the OLED module structure includes a substrate 141, a pixel defining layer 142, an electroluminescent layer 143, an encapsulation layer 144 and a circular polarizer 145. However, a circular polarizer for the OLED currently on the market has a relatively large minimum thickness, for example, being more than 60 μm, and has light transmittance lower than 45%, which is quite unfavorable for reducing a thickness of a display and power consumption.

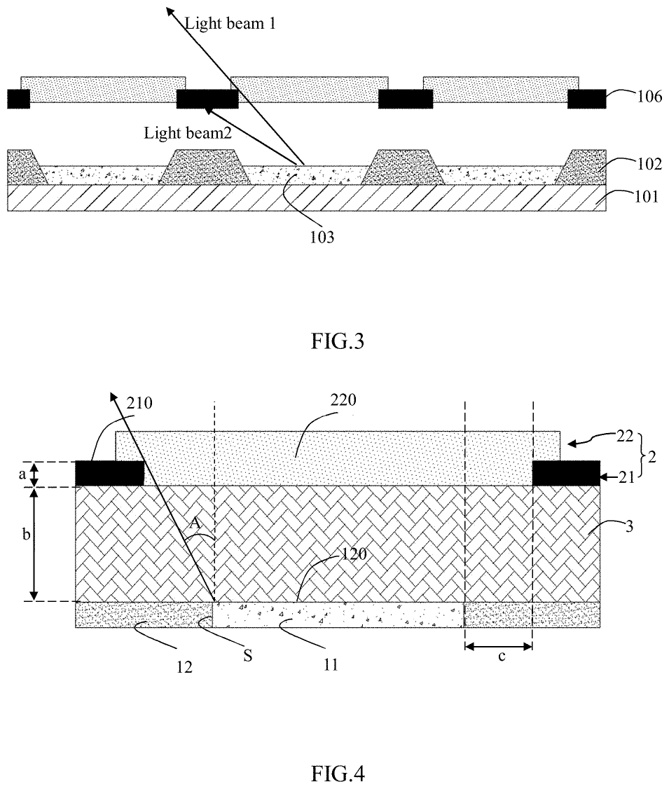

In order to eliminate these two disadvantages, a Color Filter on Encapsulation (COE) structure is adopted in the embodiments of the present disclosure. For example, as illustrated in FIG. 2, a COE structure is formed on an encapsulation layer 104; and the COE structure includes a black matrix layer 106 and a color filter layer 107. As illustrated in FIG. 3, due to existence of the black matrix layer 106, part of light (e.g., a large-angle light beam 2) emitted from the electroluminescent layer 103 will be absorbed, thereby achieving an anti-peeping effect. In addition, the COE structure fabricated on the encapsulation layer 104 replaces the circular polarizer, so light transmittance of the COE structure is up to approximately 60%, which is greatly increased as compared with that of the circular polarizer; and a total thickness of the display panel and power consumption are reduced.

According to an embodiment of the present disclosure, there is provided an anti-peeping display panel, comprising: a plurality of pixel units, each of the plurality of the pixel units including a plurality of sub-pixels, each of the plurality of the sub-pixels including: an electroluminescent layer; a color filter layer including a plurality of color filter units, the plurality of the color filter units being in one-to-one correspondence with the plurality of the sub-pixels, the color filter unit being configured to filter light emitted by a corresponding sub-pixel; and a black matrix layer including a plurality of black matrices, each of the plurality of the black matrices being located in an area adjoining adjacent color filter units, the black matrix layer being configured to block at least part of light emitted by a sub-pixel adjacent to the black matrix, and an included angle between an emission direction of the at least portion of light and a normal of a light emergent surface of the sub-pixel being greater than or equal to 40°.

In the anti-peeping display panel, because the black matrix layer absorbs large-angle emergent light, a viewer located on oblique sides (i.e., left and right sides) of the display panel cannot see an image displayed on the display panel, thereby achieving the anti-peeping effect.

At least one embodiment of the present disclosure provides an anti-peeping display apparatus. As illustrated in FIG. 4 and FIG. 8, the anti-peeping display apparatus comprises an anti-peeping display panel. For example, the anti-peeping display panel comprises a plurality of pixel units; and each of the plurality of the pixel units includes a plurality of sub-pixels 11. The anti-peeping display panel further comprises an encapsulation layer 3, a pixel defining layer 12, a black matrix layer 21, and a color filter layer 22.

In this embodiment, each of the sub-pixels 11 includes an electroluminescent layer. The color filter layer 22 includes a plurality of color filter units 220. The plurality of color filter units 220 are in one-to-one correspondence with the plurality of sub-pixels 11, and each of the color filter units 220 is configured to filter light emitted by a corresponding sub-pixel 11. The black matrix layer 21 includes a plurality of black matrices 210, and each of the black matrices 210 is located in an area adjoining adjacent color filter units 220. The black matrix 210 is configured to block at least part of light emitted by the sub-pixel 11 adjacent to the black matrix 210, and an included angle between an emission direction of the at least portion of light and a normal of a light emergent surface of the sub-pixel is greater than or equal to 40°.

In this embodiment, a COE structure 2 includes the black matrix layer 21 and the color filter layer 22; the COE structure 2 is used to absorb light emitted from an invisible region of the electroluminescent layer, so as to reduce a visible region of the electroluminescent layer. When the viewing angle is increased to a certain extent, light starts to get blocked, because the black matrix layer 21 has a light-absorbing effect. It can be seen that, the anti-peeping display panel provided by the embodiment of the present disclosure absorbs light emitted from the invisible region of the electroluminescent layer by using the COE structure 2, so as to reduce the visible region of the electroluminescent layer, which in turns implements the anti-peeping function and also solves the problem in a prior art that the LCF film cannot be applied to thin-type products. The anti-peeping display panel adopts the COE structure 2 to implement the anti-peeping function, so application of the anti-peeping display panel to thin-type products not only helps control thin-type products to have a smaller thickness, but also ensure relatively low power consumption of the thin-type products.

It should be noted that, in the embodiment of the present disclosure, the visible region is a region directly facing the electroluminescent layer along a light emission direction of the electroluminescent layer, and the invisible region is located on two sides of the visible region.

For example, the pixel defining layer 12 is provided with a plurality of openings, that is, defines a plurality of pixel regions; and each pixel region is provided therein with a sub-pixel 11. The sub-pixel 11 includes an anode and an electroluminescent layer provided on the anode. The electroluminescent layer includes, for example, an organic light-emitting material; and the organic light-emitting material is filled in the opening and located above the anode. There are various organic light-emitting materials, for example, a red light-emitting material for emitting red light, a green light-emitting material for emitting green light, and a blue light-emitting material for emitting blue light. Each opening will be filled with only one kind of organic light-emitting material. A common cathode is arranged above the organic light-emitting material and the pixel defining layer.

For example, corresponding to each opening in the pixel defining layer 12, the organic light-emitting material in the opening as well as the anode and the common cathode on upper and lower sides thereof constitute the sub-pixel 11. For example, as illustrated in FIG. 8, a plurality of adjacent sub-pixels 11 with different light-emitting colors may constitute a pixel unit. For example, a red sub-pixel unit 111, a green sub-pixel 112, and a blue sub-pixel 113 that are adjacent to each other constitute a pixel unit. In a same pixel unit, respective colors of light emitted by respective sub-pixels 11 may be mixed to produce a color that the pixel unit displays.

For example, as illustrated in FIG. 4, light generated by each sub-pixel 11 is emitted outward and enter a viewing field of a viewer. Each sub-pixel 11 emits light outward from an upper surface, so the upper surface of the sub-pixel 11 or an upper surface of the electroluminescent layer may be regarded as a light emergent surface 120.

For example, as illustrated in FIG. 4, in a direction perpendicular to the light emergent surface 120 of the sub-pixel 11, each of the sub-pixels 11 does not overlap with the black matrix layer 21. A light emergent surface 120 of each of the sub-pixels 11 includes at least one side edge S, and a maximum value of an included angle A between light emitted from the side edge S and propagating outward through the corresponding color filter unit 220 and a normal of the light emergent surface 120 is approximately 40°. In this way, the anti-peeping effect of the display panel can be effectively improved, so that viewers located on both sides of the display panel cannot see the displayed image.

Optionally, both the black matrix layer 21 and the color filter layer 22 may be made from low-temperature curable materials, For example, the black matrix layer 21 and the color filter layer 22 are directly formed on the encapsulation layer 3 by using patterning processes such as “coating→exposing→developing”. Optionally, as illustrated in FIG. 4, the pixel defining layer 12 defines a pixel region; and the sub-pixel 11 is located in the pixel region. The color filter units 220 in the color filter layer 22 are in one-to-one correspondence with the sub-pixels 11 in the electroluminescent layer; and an orthographic projection of the sub-pixel 11 on the color filter unit 220 is located within the color filter unit 220. A red filter unit is located above a red sub-pixel (R sub-pixel), a green filter unit is located above a green sub-pixel (G sub-pixel), and a blue filter unit is located above a blue sub-pixel (B sub-pixel). The coverage area of the color filter unit is larger than an area of the sub-pixel, that is, the color filter unit exceeds an edge of the sub-pixel to obtain trichromatic light. Optionally, the black matrix layer 21 includes a black matrix 210, and an orthographic projection of the black matrix 210 on the pixel defining layer 12 is located within the pixel defining layer 12 to prevent the black matrix from absorbing light emitted from the visible region of the electroluminescent layer.

Generally speaking, a viewing angle which is greater than 40° means a wide viewing angle, so having an anti-peeping function means that brightness of the screen has been reduced to almost invisible at a viewing angle of 40°. For a general LCF film, the invisibility may be quantitatively defined as the brightness is small than or equal to 5% of the front view brightness.

For example, a distance between each of the sub-pixels and an orthographic projection of a black matrix adjacent thereto on the pixel defining layer is less than or equal to 3 microns. As illustrated in FIG. 4, a thickness of the black matrix layer 21 is a; a vertical distance from a light emergent surface 120 of the sub-pixel 11 to a surface of the black matrix 21 that is close to the sub-pixel is b; and a distance between the orthographic projection of the black matrix on the pixel defining layer 12 and the side edge S of the sub-pixel 11 is c. Further, in at least one example, the vertical distance b is a thickness of the encapsulation layer 3. The inventor finds that: if it is to increase viewing angle attenuation, values of a and b need to be as large as possible, while the value of c as small as possible. In condition that c=0, a sum of a and b at least equals to 40 μm, as a result, the viewing angle is 40° and brightness attenuation is greater than or equal to 95% of the front view brightness. However, in actual design, because the value of c affects the light reflectivity, the greater the value of c, the greater the light reflectivity. For example, the distance c is approximately in a range of 0 μm<c≤3 μm. Considering actual production capability, the black matrix layer 21 cannot be made very thick, so b needs to be increased. For example, a ratio of b to a is greater than or equal to 8. Further, in order to prevent the anti-peeping display panel from being too thick to be applied to thin-type products, for example, a is approximately in a range of 0 μm<a≤5 μm and b is approximately in a range of 40 μm≤b≤80 μm. The wording “approximately” here may be understood as a value range in process tolerance or measurement tolerance that does not strictly require numerical limits.

Optionally, the thickness a of the black matrix layer 21 is 0.5 μm, 0.8 μm, 1.3 μm, 2.5 μm, 3.3 μm, 4.7 μm, 5 μm, etc.; on one hand, the above-mentioned thickness in the embodiments avoids an increased process difficulty caused by an excessive thickness; on the other hand, the anti-peeping display panel may achieve the anti-peeping effect. Optionally, a thickness b of the encapsulation layer 3 is 40 μm, 46 μm, 55 μm, 62 μm, 73.5 μm, 80 μm, etc.; on one hand, the above-mentioned thickness in the embodiments avoids an increased process difficulty caused by an excessive thickness; on the other hand, the anti-peeping display panel may achieve the anti-peeping effect. Optionally, the distance c between the orthographic projection of the black matrix 210 on the pixel defining layer 12 and the side edge S of the sub-pixel 11 adjacent thereto is 0 μm, 0.2 μm, 0.65 μm, 1.4 μm, 2.2 μm, 3 μm, etc., the above-mentioned thickness in these embodiments may all achieve the anti-peeping effect. It should be pointed out that, by adjusting the values of a, b and c, the viewing angle of the anti-peeping display panel can be adjusted to meet different requirements.

Because sizes of the R sub-pixel, the G sub-pixel, and the B sub-pixel are different from one another, the brightness attenuation rates of their viewing angle are also different from one another. Generally speaking, red light has longest service life, and blue light has shortest service life. Thus, in terms of aperture ratio, red light is the smallest and blue light is the largest. In order to keep the brightness attenuations of the R, G, and B sub-pixels relatively balanced, the embodiment of the present disclosure may adopt asymmetric design for a line width of the opening in the BM of the sub-pixel. For example, a distance between the red sub-pixel and an orthographic projection of the black matrix adjacent to the red sub-pixel on the pixel defining layer is greater than or equal to a distance between the green sub-pixel and an orthographic projection of the black matrix adjacent to the green sub-pixel on the pixel defining layer. The distance between the green sub-pixel and the orthographic projection of the black matrix adjacent to the green sub-pixel on the pixel defining layer is greater than or equal to a distance between the blue sub-pixel and an orthographic projection of the black matrix adjacent to the blue sub-pixel on the pixel defining layer. For example, as illustrated in FIG. 5, the sub-pixel 11 includes a red sub-pixel 111, a green sub-pixel 112, and a blue sub-pixel 113. A distance between an orthographic projection of a black matrix 210 on a pixel defining layer 12 and at least one side edge of the red sub-pixel 111 is defined as c_{R}, a distance between an orthographic projection of a black matrix 210 on the pixel defining layer 12 and at least one side edge of the green sub-pixel 112 be c_{G}, and a distance between an orthographic projection of a black matrix 210 on the pixel defining layer 12 and at least one side edge of the blue sub-pixel 113 be c_{B}. In one example, c_{R}>c_{G}>c_{B}. For example, c_{R}=2.8 μm, c_{G}=2.0 μm, c_{B}=1.8 μm; or, c_{R}=1.5 μm, c_{G}=0.8 μm, c_{B}=0.6 μm; or, c_{R}=2.7 μm, c_{G}=2.2 μm, c_{B}=1.0 μm, etc, in the embodiments, the brightness attenuations of the R, G, and B sub-pixels are kept relatively balanced.

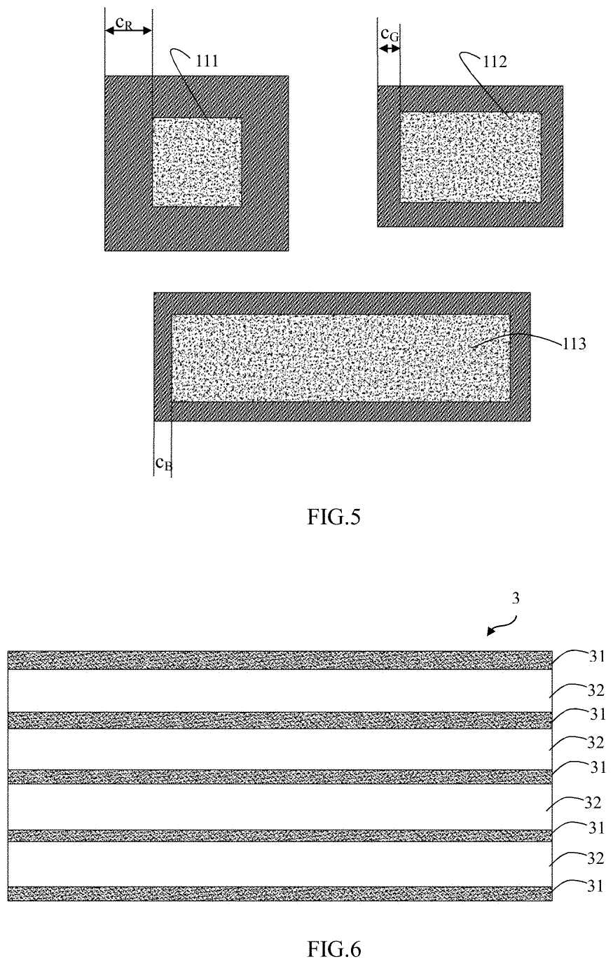

The encapsulation layer can protect the electroluminescent layer from erosion by external moisture and oxygen, and play a role as an encapsulating material. Considering that there may be a process difficulty in preparing an excessively thick encapsulation layer 3, in the embodiment of the present disclosure, the encapsulation layer 3 is designed as an “inorganic\organic” alternately stacked structure. In at least some embodiments, the encapsulation layer includes a first layer closest to the pixel unit and a last layer closest to the color filter layer; and both the first layer and the last layer are inorganic material layers. For example, as illustrated in FIG. 6, the encapsulation layer 3 includes four organic material layers 32; the encapsulation layer includes a first layer closest to the pixel unit and a last layer closest to the color filter layer; and both the first layer and the last layer are inorganic material layers 31. Optionally, in order to further simplify the process, an “inorganic\organic\inorganic” three-layer structure may be adopted, which can reduce the process difficulty as much as possible while ensuring the thickness of the encapsulation layer 3. Optionally, the encapsulation layer includes at least two organic material layers, for example, an “inorganic\organic\inorganic\organic\inorganic” five-layer structure is adopted, which may reduce the process difficulty as much as possible while ensuring the thickness of the encapsulation layer 3.

Optionally, the inorganic material layer 31 may be made of silicon nitride or silicon oxynitride, which is typically prepared by atomic layer deposition; and the organic material layer 32 may be made of polymethylmethacrylate (PMMA), which is generally prepared by using an ink jet printing (IJP) method. Optionally, a thickness of the inorganic material layer 31 is approximately from 0.5 μm to 1 μm; a thickness of the organic material layer 32 is approximately from 8 μm to 20 μm; and a total thickness of the encapsulation layer 3 is approximately from 40 μm to 80 μm, so as to reduce the process difficulty. Optionally, the thickness of the inorganic material layer 31 is 0.5 μm, 0.6 μm, 0.8 μm, 0.9 μm, 1 μm, etc.; and the thickness of the organic material layer 32 is 8 μm, 12 μm, 14 μm, 17 μm, 18.5 μm, 20 μm, etc. The wording “approximately” here may be understood as a value range in process tolerance or measurement tolerance that does not strictly require numerical limits.

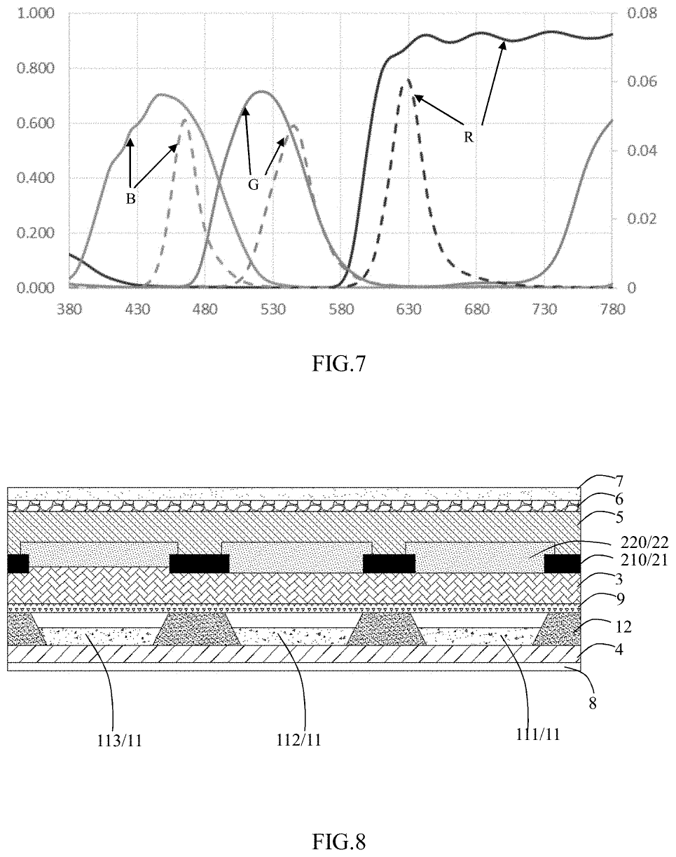

In addition, in the situation that the viewing angle is increased to a certain extent, light of a certain sub-pixel exits from a color filter unit corresponding to another sub-pixel (i.e., the adjacent sub-pixel) adjacent to the certain sub-pixel, due to that the encapsulation layer 3 is relatively thick. Such a situation seems to cause oblique light leakage, resulting in failure to implement the narrow viewing angle function. However, through tests, as illustrated in FIG. 7, by comparing the emission spectrums of the electroluminescent layers (ELs) of the R sub-pixel, the G sub-pixel, and the B sub-pixel as well as the transmission spectrum of the color filter layer (CF), it can be seen that, the brightness of the natural light is greatly reduced after passing through any one of two color filter units. In FIG. 7, a solid line represents the CF transmission spectrum, a dotted line represents the EL emission spectrum, R represents the red sub-pixel, G represents the green sub-pixel, and B represents the blue sub-pixel.

In addition, in conjunction with Table 1 below, it can be seen that, through theoretical calculation, an intensity of the spectrum after passing through the adjacent CF is almost negligible as compared with an intensity of the EL spectrum. Therefore, it may be considered that an effect of light emission from the color filter unit corresponding to the adjacent sub-pixel is almost the same as an effect of light emission from the black matrix, without any phenomenon of large-angle light leakage.

TABLE 1

| | Y (by calculation of tristimulus values) |
|---|---|
| R EL | 0.11 |
| R EL + G CF | 0.002 |
| R EL + B CF | 0.0002 |
| G EL | 0.35 |
| G EL + R CF | 0.005 |
| G EL + B CF | 0.004 |
| B EL | 0.03 |
| B EL + R CF | 0.0003 |
| B EL + G CF | 0.006 |

For example, as illustrated in FIG. 8, the anti-peeping display apparatus further comprises a driving substrate, the anti-peeping display panel is provided on the driving substrate; the driving substrate includes a base substrate 8 and a driving circuit 4; and the driving circuit 4 is configured to drive each of the sub-pixels to emit light. The driving circuit 4 includes, for example, a plurality of thin film transistors. The base substrate 8 may be a glass substrate or a flexible substrate.

For example, the anti-peeping display apparatus further comprises a protective layer 5, a touch sensing layer 6 and a cover plate 7 that are sequentially arranged on a side of the anti-peeping display panel that is away from the driving substrate 4. The anti-peeping display apparatus absorbs light emitted from the invisible region of the electroluminescent layer by using the COE structure 2, to reduce the visible region of the electroluminescent layer, thereby implementing the anti-peeping function, and applying the anti-peeping display panel to thin-type products. The anti-peeping display apparatus may be a flexible foldable anti-peeping display apparatus; and the viewing angle of the visible region of the anti-peeping display apparatus can be adjusted by adjusting the thickness a of the black matrix layer 21, the thickness b of the encapsulation layer 3, and the distance c between the orthographic projection of the black matrix 210 on the pixel defining layer 12 and the side edge of the sub-pixel 11, so as to meet different requirements on the viewing angle.

Optionally, the display apparatus may further comprise a Capping Layer (CPL) 9 provided on a side of the sub-pixel that is close to the encapsulation layer 3.

It can be seen that, the anti-peeping display panel and the anti-peeping display apparatus provided by the embodiments of the present disclosure absorb light emitted from the invisible region of the electroluminescent layer by using the black matrix layer to reduce the visible region of the electroluminescent layer, thereby implementing the anti-peeping function. Moreover, the COE structure, which has advantages such as small thickness and high light transmittance, can be applied to thin-type products (e.g., organic light-emitting display panels, etc.) to implement the anti-peeping function of the thin-type products. Application of the anti-peeping display panel to the thin-type products not only helps control thin-type products to have a smaller thickness, but also ensure relatively low power consumption of the thin-type products.

1. An anti-peeping display panel, comprising:
a plurality of pixel units, each of the plurality of the pixel units comprising a plurality of sub-pixels, each of the plurality of the sub-pixels comprising an electroluminescent layer;
a color filter layer, comprising a plurality of color filter units, the plurality of the color filter units being in one-to-one correspondence with the plurality of the sub-pixels, each of the plurality of the color filter units being configured to filter light emitted from a corresponding sub-pixel; and
a black matrix layer, comprising a plurality of black matrices, each of the plurality of the black matrices being located in an area adjoining adjacent color filter units, the black matrix being configured to block at least part of light emitted from the sub-pixel adjacent to the black matrix, and an included angle between an emission direction of the at least portion of light and a normal of a light emergent surface of the sub-pixel being greater than or equal to 40°.

2. The anti-peeping display panel according to claim 1, wherein each of the sub-pixels does not overlap with the black matrix adjacent to the each of the sub-pixels in a direction perpendicular to the light emergent surface of each of the sub-pixels; and
wherein the light emergent surface of each of the sub-pixels comprises at least one side edge, and a maximum value of an included angle between light emitted through the at least one side edge and propagating outward through the color filter unit corresponding to the sub-pixel and the normal is 40°.

3. The anti-peeping display panel according to claim 2, further comprising a pixel defining layer, wherein the pixel defining layer defines a plurality of pixel regions, the plurality of the sub-pixels are respectively located within the plurality of the pixel regions, and an orthographic projection of each of the black matrices on the pixel defining layer is located within the pixel defining layer.

4. The anti-peeping display panel according to claim 3, wherein the light emergent surface of each of the sub-pixels comprises at least one side edge, and a distance between the at least one side edge and an orthographic projection of the black matrix adjacent to the at least one side edge on the pixel defining layer is from 0 to 3 microns.

5. The anti-peeping display panel according to claim 4, wherein the light emergent surface of each of the sub-pixels has a rectangle shape and comprises four side edges, a distance between each of the four side edges and the orthographic projection of the black matrix adjacent to the side edge on the pixel defining layer is zero; and
wherein a thickness of the black matrix layer is a, and a vertical distance from the light emergent surface of each of the sub-pixels to a surface of the black matrix that is close to the sub-pixel is b, wherein, a+b≥40 microns.

6. The anti-peeping display panel according to claim 4, wherein the light emergent surface of each of the sub-pixels has a rectangle shape and comprises four side edges, a distance between each of the four side edges and the orthographic projection of the black matrix adjacent to the side edge on the pixel defining layer is greater than zero; and
wherein a thickness of the black matrix layer is a, and a vertical distance from the light emergent surface of each of the sub-pixels to a surface of the black matrix that is close to the sub-pixel is b, wherein, b>a, and a ratio of b to a is greater than or equal to 8.

7. The anti-peeping display panel according to claim 6, wherein a is approximately in a range from 0 microns to 5 microns; and b is approximately in a range from 40 microns to 80 microns.

8. The anti-peeping display panel according to claim 1, further comprising an encapsulation layer, wherein the encapsulation layer is located between the color filter layer and each of the sub-pixels and is configured to encapsulate the plurality of the pixel units; and the encapsulation layer comprises an inorganic material layer and an organic material layer which are alternately arranged.

9. The anti-peeping display panel according to claim 8, wherein the encapsulation layer comprises at least two organic material layers; the encapsulation layer comprises a first layer closest to the pixel unit and a last layer closest to the color filter layer; and the first layer and the last layer are both the inorganic material layers.

10. The anti-peeping display panel according to claim 9, wherein a thickness of the inorganic material layer is approximately from 0.5 microns to 1 micron; and a thickness of the organic material layer is approximately from 8 microns to 20 microns.

11. The anti-peeping display panel according to claim 8, wherein a vertical distance from the light emergent surface of each of the sub-pixels to a surface of the black matrix that is close to the sub-pixel is equal to the thickness of the encapsulation layer.

12. The anti-peeping display panel according to claim 1, wherein the sub-pixels comprise a red sub-pixel, a green sub-pixel, and a blue sub-pixel; and
wherein a distance between the red sub-pixel and an orthographic projection of the black matrix adjacent to the red sub-pixel on the pixel defining layer is greater than or equal to a distance between the green sub-pixel and an orthographic projection of the black matrix adjacent to the green sub-pixel on the pixel defining layer.

13. The anti-peeping display panel according to claim 12, wherein the distance between the green sub-pixel and the orthographic projection of the black matrix adjacent to the green sub-pixel on the pixel defining layer is greater than or equal to a distance between the blue sub-pixel and an orthographic projection of the black matrix adjacent to the blue sub-pixel on the pixel defining layer.

14. An anti-peeping display apparatus, comprising the anti-peeping display panel according to claim 1.

15. The anti-peeping display apparatus according to claim 14, further comprising: a driving substrate, wherein the anti-peeping display panel is provided on the driving substrate; and
wherein the driving substrate comprises a driving circuit, the driving circuit is configured to drive each of the sub-pixels to emit light.

16. The anti-peeping display apparatus according to claim 15, further comprising: a protective layer, a touch sensing layer and a cover plate that are sequentially arranged on a side of the anti-peeping display panel that is away from the driving substrate.
